(19) United States
(12) Patent Application Publication
(10) Pub. No.: US 2008/0174359 A1
(43) Pub. Date: Jul. 24, 2008

(54) SEMICONDUCTOR INTEGRATED CIRCUIT

(76) Inventors: Kenichi OSADA, Tokyo (JP); Masanao Yamaoka, Kodaira (JP); Shigenobu Komatsu, Kokubunji (JP)

Correspondence Address: MILES & STOCKBRIDGE PC, 1751 PINNACLE DRIVE, SUITE 500, MCLEAN, VA, 22102-3833, US

(21) Appl. No.: 11/942,939

(22) Filed: Nov. 20, 2007

(30) Foreign Application Priority Data
Jan. 24, 2007 (JP) 2007-013361

(51) Int. Cl. H03K 3/01

(52) U.S. Cl. 327/534

(57) ABSTRACT

A substrate bias technique is used in an active mode enabling a high yield, and an operating consumption power and the fluctuation of a signal delay in signal processing are reduced in the active mode. The additional PMOS and NMOS of the additional capacitance circuit are produced in the same production process as the PMOSs and the NMOSs of the CMOS circuits. The gate capacitance of the additional PMOS is coupled between the power supply wiring and the N well and the gate capacitance of the additional NMOS is coupled between the ground wiring and the P well. The noise on the power supply wiring is transmitted to the N well through the gate capacitance and the noise on the ground wiring is transmitted to the P well through the gate capacitance. The fluctuation of noise on the substrate bias voltage between the source and the well of PMOS and NMOS of the CMOS circuits is reduced.

### CLAIM OF PRIORITY

The present application claims priority from Japanese allocation JP 2007-013361 filed on Jan. 24, 2007, the content of which is hereby incorporated by reference into this application.

### FIELD OF THE INVENTION

The present invention relates to a semiconductor integrated circuit, and in particular, to a technique which uses a substrate bias technique enabling high yield in an active mode and is useful to reduce an operation power consumption for signal processing and fluctuation of signal delay in the active mode.

### BACKGROUND OF THE INVENTION

A short channel effect resulting from the miniaturization of a semiconductor device has lowered the threshold voltage of a MOS transistor and obviously increased a sub-threshold leak current. A sub threshold characteristic refers to a characteristic at not greater than the threshold voltage of the MOS transistor, and leak current generated in a weak inversion condition of a MOS silicon surface is called sub-threshold leak current. There is well-known a substrate bias technique as a method of decreasing such a leak current. A predetermined substrate bias voltage is applied to a semiconductor substrate (referred to as “well” for a CMOS) in which the MOS transistor is formed to enable decreasing a sub-threshold leak current.

The following non-Patent Document 1 describes that a substrate bias voltage is switched in an active and a standby mode. In the active mode, an NMOS substrate bias voltage Vbn applied to the P well of an NMOS in a CMOS is set to a ground voltage Vss (0 volts) applied to the N-type source of the NMOS. In addition, a PMOS substrate bias voltage Vbp applied to the N well of the PMOS in the CMOS is set to a power supply voltage Vdd (1.8 volts) applied to the P-type source of the PMOS. In the standby mode in which a sub-threshold leak current is decreased, the NMOS substrate bias voltage Vbn applied to the P well is set to a negative voltage (−1.5 volts) of a reverse bias with respect to the ground voltage VSS (0 volts) applied to the N-type source of the NMOS in the CMOS. In addition, the PMOS substrate bias voltage Vbp applied to the N well is set to a positive voltage (3.3 volts) of a reverse bias with respect to the power supply voltage Vdd (1.8 volts) applied to the P-type source of the PMOS in the CMOS.

In addition, the following Patent Document 1 describes that a switching element for switching the substrate bias voltage is dispersedly arranged in available cells inside a logic circuit to decrease noise inducting latch up at the time of switching the substrate bias voltage. The Patent Document 1 also describes that the P-type source of the PMOS and the N-type source of the NMOS in the available cells are coupled to the power supply voltage Vdd and the ground voltage VSS respectively to add capacitance for reducing noise.

[Non-Patent Document 1] Hiroyuki Mizuno et al., “A 18 μA-Standby-Current 1.8 V 200 MHz Microprocess or with Self Substrate-Biased Data-Retention Mode”, 1999 IEEE International Solid-State Circuits Conference DIGEST OF TECHNICAL PAPERS, pp. 280-281, 468.

[Patent Document 1] International Publication WO00/65650

### SUMMARY OF THE INVENTION

Prior to the present invention, the present inventors investigated the use of an active substrate bias technique in which a substrate bias voltage is applied to a MOS transistor in a active mode in which input signal is processed. The technique is such that the level of the substrate bias voltage applied across the source and the substrate (well) of MOS transistor is adjusted in the active mode to compensate the dispersion of the threshold voltage of the MOS transistor.

A conventional substrate bias technique is such that a sub-threshold leak current in standby mode caused by decrease in a threshold voltage of the MOS transistor due to the miniaturization of a semiconductor device is decreased. However, the dispersion in threshold voltages of the MOS transistor due to further miniaturization of semiconductor device has got obvious between chips. That is to say, excessively low threshold voltage of the MOS transistor significantly increases operation power consumption in an active mode in which a semiconductor integrated circuit performs signal processing of a digital or an analog input signal. On the other hand, excessively high threshold voltage of the MOS transistor significantly decreases an operating speed in an active mode in which the semiconductor integrated circuit performs signal processing of a digital or an analog input signal. This significantly narrows a process window of threshold voltages of the MOS transistor at the time of producing a MOS LSI to substantially lower the yield of the MOS LSI.

To solve such a problem the present inventors investigated the active substrate bias technique the prior to the present invention. In the active substrate bias technique, the threshold voltage of a produced MOS transistor is measured. If the threshold voltage is substantially dispersed, the level of a substrate bias voltage is adjusted to control the dispersion within a predetermined error range. A substrate bias voltage of a reverse bias or a substantially shallow bias is applied to the substrate (well) of the MOS transistor with respect to the operating voltage applied to the source of the MOS transistor.

Thus, the use of the active substrate bias technique enables improving the yield of the MOS LSI and preventing an operation power consumption from increasing in the active mode of signal processing and an operating speed from lowering in the active mode of signal processing.

On the other hand, the use of the active substrate bias technique produces a new problem. The problem is that charging and discharging current for digital and analog input signal in the active mode induces noise onto the ground voltage Vss of the N-type source of the NMOS in the CMOS and the power supply voltage Vdd of the P-type of the PMOS. On the other hand, the level of the NMOS substrate bias voltage Vbn and the PMOS substrate bias voltage Vbp applied to the P well of the NMOS and the N well of the PMOS respectively is substantially stably maintained. For this reason, since the bias voltage between the source and the substrate varies, the threshold voltage of the MOS transistor varies. As a result, the investigation of the present inventors revealed that a problem was raised in that the operation power consumption of signal processing and signal delay are varied.

For this reason, the present invention was made based on the investigation of the present inventors preceding to the present invention. An object of the present invention is to use a substrate bias technique enabling high yield in an active mode and reduce an operation power consumption for signal processing and fluctuation of signal delay in the active mode.

The above and other objects and novel features of the present invention will be apparent from the description of the present specification and the accompanying drawings.

The following is a brief description of a typical one out of the inventions disclosed in the present application.

That is to say, a typical semiconductor integrated circuit according to the present invention includes a CMOS circuit processing an input signal and an additional capacitance circuit produced in the same production process as the CMOS circuit. The CMOS circuit and the additional capacitance circuit include PMOSs and an additional PMOS with an N well and NMOSs and an additional NMOS with a P well. The sources of the PMOSs of the CMOS circuit and the additional PMOS of the additional capacitance circuit are electrically coupled to a first operating voltage wiring and the sources of the NMOSs of the CMOS circuit and the additional NMOS of the additional capacitance circuit are electrically coupled to a second operating voltage wiring. The N well can be supplied with a PMOS substrate bias voltage and the P well can be supplied with an NMOS substrate bias voltage. The gate of the additional PMOS of the additional capacitance circuit is electrically coupled to the N well and the gate of the additional NMOS of the additional capacitance circuit is electrically coupled to the P well.

For this reason, according to the typical semiconductor integrated circuit, a parasitic capacitance of gate of the additional PMOS of the additional capacitance circuit is coupled between the first operating voltage wiring and the N well. A parasitic capacitance of gate of the additional NMOS in the additional capacitance circuit is coupled between the second operating voltage wiring and the P well. This transmits charging and discharging noise on the first operating voltage wiring to a PMOS substrate bias voltage through the parasitic capacitance of gate of the additional PMOS and transmits charging and discharging noise on the second operating voltage wiring to an NMOS substrate bias voltage through the parasitic capacitance of gate of the additional NMOS. Accordingly, noise fluctuation of the substrate bias voltage between the source and the well of the PMOS and between the source and the well of the NMOS is reduced. As a result, the fluctuation of operating consumption power and the signal delay can be reduced in signal processing caused by charging and discharging current produced by signal processing in the active mode due to the use of the substrate bias technique in the active mode. In addition, it is enabled to form a compensation capacitance for reducing noise of a gate parasitic capacitance of the additional PMOS of the additional capacitance circuit produced in the same production process as the CMOS and a gate parasitic capacitance of the additional NMOS at low cost.

The following is the brief description of the effects obtained by typical ones out of the inventions disclosed in the present application.

That is to say, according to the present invention, it is enabled to use the substrate bias technique enabling high yield in an active mode and reduce an operation power consumption for signal processing and fluctuation of signal delay in the active mode.

### BRIEF DESCRIPTION OF THE DRAWINGS

FIG. 1 is a circuit diagram illustrating a semiconductor integrated circuit according to one embodiment of the present invention;

FIG. 2 is a layout illustrating the device planar structure of the semiconductor integrated circuit in FIG. 1;

FIGS. 3A and 3B are cross sections of the essential part of FIG. 2;

FIG. 4 is wave forms describing an operation in an active mode in the semiconductor integrated circuit illustrated in FIGS. 1, 2 and 3;

FIG. 5 is a circuit diagram of a system LSI being the semiconductor integrated circuit according to one embodiment of the present invention;

FIG. 6 is a circuit diagram illustrating the semiconductor integrated circuit according to another embodiment of the present invention;

FIG. 7 is a layout illustrating the device planar configuration of the semiconductor integrated circuit in FIG. 6;

FIGS. 8A and 8B are cross sections of the essential part of FIG. 7;

FIG. 9 is a circuit diagram illustrating the semiconductor integrated circuit according to further another embodiment of the present invention;

FIG. 10 is a layout illustrating the device planar configuration of the semiconductor integrated circuit in FIG. 9;

FIGS. 11A and 11B are cross sections of the essential part of FIG. 10;

FIGS. 12A and 12B are cross sections of the essential part of FIG. 10;

FIG. 13 is a circuit diagram illustrating a semiconductor integrated circuit compensating the dispersion of a threshold voltage in a MOS transistor of a standard cell in the core of FIG. 1;

FIGS. 14A and 14B are circuit diagrams illustrating an example of the configuration of a control memory of an LSI chip in FIG. 13;

FIG. 15 is a chart illustrating the relationship of voltages of each portion of the semiconductor integrated circuit in FIG. 13;

FIGS. 16A and 16B are graphs describing the distribution of the threshold voltage Vth of a produced MOS LSI;

FIG. 17 is a circuit diagram describing wafer test including a large number of LSI chips illustrating in FIG. 13;

FIG. 18 is a flow chart describing the method of producing a semiconductor integrated circuit including the flow of wafer test and wafer process;

FIG. 19 is a circuit diagram illustrating the semiconductor integrated circuit according to further another embodiment of the present invention;

FIGS. 20A and 20B are graphs describing the distribution of the threshold voltage Vth in the semiconductor integrated circuit illustrating in FIG. 19;

FIG. 21 is a chart illustrating the relationship of voltages of each portion of the semiconductor integrated circuit in FIG. 19; and

FIG. 22 is a cross section illustrating the semiconductor integrated circuit according to further another embodiment of the present invention.

### DETAILED DESCRIPTION OF THE PREFERRED EMBODIMENTS

### Typical Embodiment

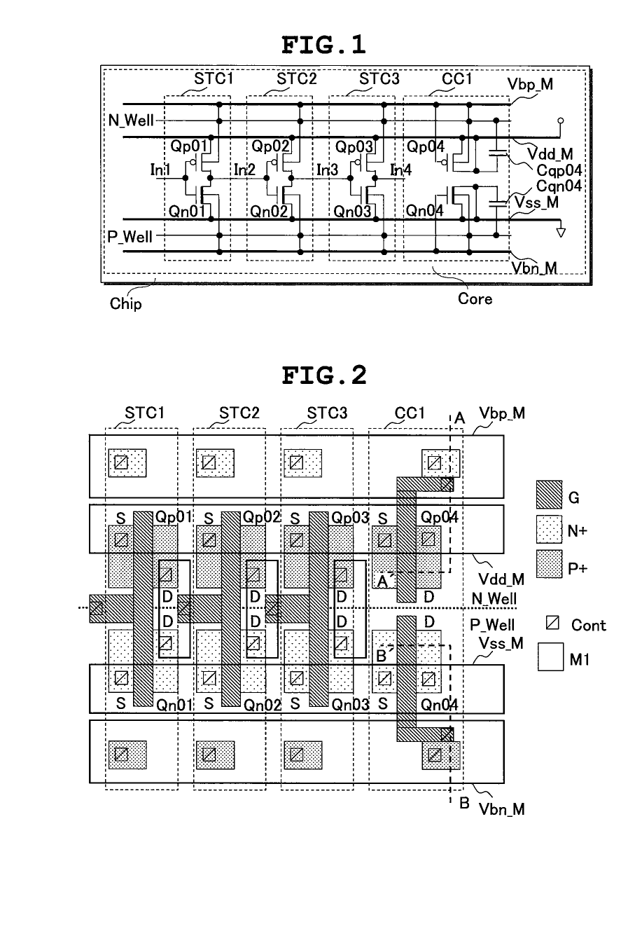

A typical embodiment in the inventions disclosed in the present application is briefly described. The parenthesized reference characters in the drawings to be referred in brief description of the typical embodiment merely exemplify one included in the concept of components parenthesized.

[1] A semiconductor integrated circuit (Chip) according to the typical embodiment of the present invention includes a CMOS circuit (ST1, ST2 and ST3) for processing an input signal (In1) and an additional capacitance circuit (CC1) produced in the same production process as the CMOS circuit. The CMOS circuit and the additional capacitance circuit include a PMOS (Qp01, Qp02 and Qp03) and additional PMOS (Qp04) with an N well (N_Well) and a NMOS (Qn01, Qn02 and Qn03) and additional NMOS (Qn04) with an P well (P_Well). The source of the PMOS of the CMOS circuit and the source of the additional PMOS of the additional capacitance circuit are electrically coupled to a first operating voltage wiring (Vdd_M). The source of the NMOS of the CMOS circuit and the source of the additional NMOS of the additional capacitance circuit are electrically coupled to a second operating voltage wiring (Vss_M). The N well can be supplied with a PMOS substrate bias voltage (Vbp) and the P well can be supplied with an NMOS substrate bias voltage (Vbn). The gate electrode (G) of the additional PMOS (Qp04) of the additional capacitance circuit (CC1) is electrically coupled to the N well (N_well). The gate electrode (G) of the additional NMOS (Qn04) of the additional capacitance circuit (CC1) is electrically coupled to the P well (P_well) (refer to FIGS. 1, 2 and 3).

For this reason, according to the embodiment, a parasitic capacitance (Cqp04) of gate of the additional PMOS in the additional capacitance circuit is coupled between the first operating voltage wiring and the N well. A parasitic capacitance (Cqn04) of gate of the additional NMOS in the additional capacitance circuit is coupled between the second operating voltage wiring and the P well. This transmits charging and discharging noise on the first operating voltage wiring to a PMOS substrate bias voltage through the parasitic capacitance of gate of the additional PMOS and transmits charging and discharging noise on the second operating voltage wiring to an NMOS substrate bias voltage through the parasitic capacitance of gate of the additional NMOS. As a result, it is enabled to reduce the fluctuation of the signal delay in a signal processing resulting from a charging and discharging current produced by signal processing in the active mode due to the use of the substrate bias technique in the active mode (refer to FIG. 4).

In a preferable semiconductor integrated circuit (Chip), a source-gate overlap capacitance between the source (S) and the gate electrode (G) of the additional PMOS (Qp04) of the additional capacitance circuit (CC1) and a source-well junction capacitance between the source (S) and the N well (N_well) of the additional PMOS (Qp04) of the additional capacitance circuit (CC1) are coupled at least in parallel between the first operating voltage wiring (Vdd_M) and the N well (N_Well). The source-gate overlap capacitance between the source (S) and the gate electrode (G) of the additional NMOS (Qn04) of the additional capacitance circuit (CC1) and the source-well junction capacitance between the source (S) and the P well (P_well) of the additional NMOS (Qn04) of the additional capacitance circuit (CC1) are coupled at least in parallel between the second operating voltage wiring (Vss_M) and the P well (P_Well).

In a more preferable semiconductor integrated circuit (Chip), the source (S) of the additional PMOS (Qp04) of the additional capacitance circuit (CC1) is electrically coupled to the drain (D) thereof and the source (S) of the additional NMOS (Qn04) of the additional capacitance circuit (CC1) is electrically coupled to the drain (D) thereof. The drain-gate overlap capacitance between the drain (D) and the gate electrode (G) of the additional PMOS (Qp04) of the additional capacitance circuit (CC1) and the drain-well junction capacitance between the drain (D) and the N well (N_well) of the additional PMOS (Qp04) of the additional capacitance circuit (CC1) are further coupled in parallel between the first operating voltage wiring (Vdd_M) and the N well (N_Well). The drain-gate overlap capacitance between the drain (D) and the gate electrode (G) of the additional NMOS (Qn04) of the additional capacitance circuit (CC1) and the drain-well junction capacitance between the drain (D) and the P well (P_well) of the additional NMOS (Qn04) of the additional capacitance circuit (CC1) are further coupled in parallel between the second operating voltage wiring (Vss_M) and the P well (P_Well).

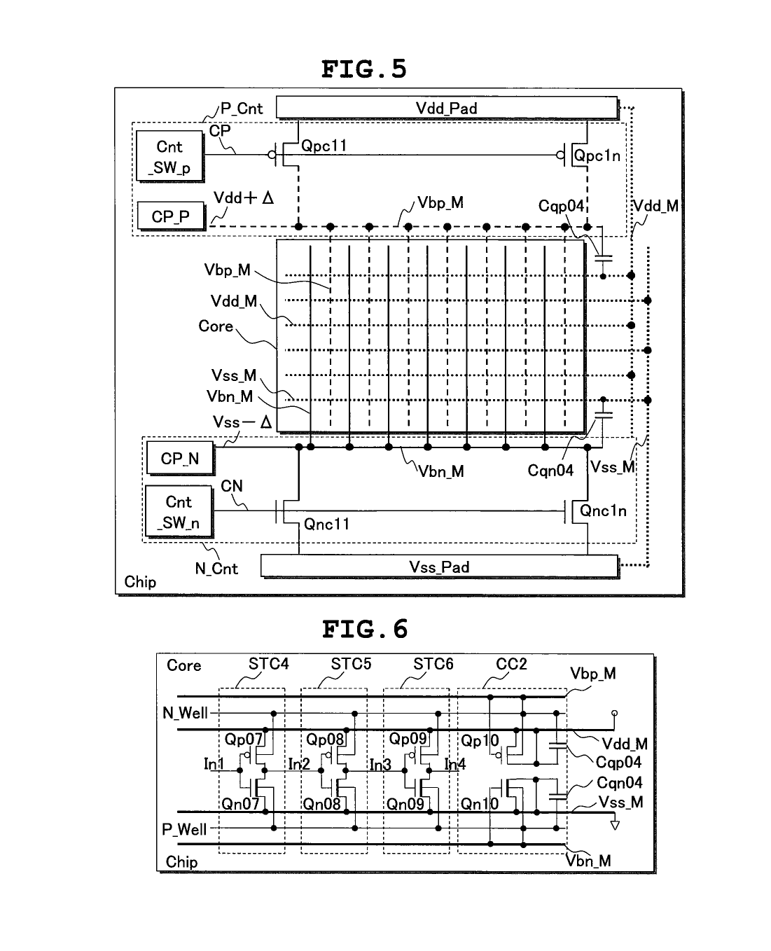

A further more preferable semiconductor integrated circuit (Chip) includes a first voltage generating unit (CP_P) for generating the PMOS substrate bias voltage (Vbp) from the first operating voltage (Vdd) supplied to the first operating voltage wiring (Vdd_M) and a second voltage generating unit (CP_N) for generating the NMOS substrate bias voltage (Vbn) from the second operating voltage supplied to the second operating voltage wiring (Vss_M) (refer to FIG. 5).

In a semiconductor integrated circuit (Chip) according to one specific embodiment, the PMOS substrate bias voltage (Vbp) supplied to the N well is reversely biased with respect to the first operating voltage (Vdd) supplied to the source of the PMOS of the CMOS circuit. The NMOS substrate bias voltage (Vbn) supplied to the P well is reversely biased with respect to the second operating voltage (Vss) supplied to the source of the NMOS of the CMOS circuit. The supply of the PMOS substrate bias voltage (Vbp) set to be higher in level than the first operating voltage (Vdd) to the N well controls the PMOS (Qp01, Qp02 and Qp03) with the N well (N_Well) at a high threshold voltage and a low leak current. The supply of the NMOS substrate bias voltage (Vbn) set to be lower in level than the second operating voltage (Vss) to the P well controls the NMOS (Qn01, Qn02 and Qn03) with the P well (P_Well) at a high threshold voltage and low leak current (refer to FIGS. 16A and 16B).

A semiconductor integrated circuit (Chip) according to another specific embodiment includes a control memory (Cnt_MM) which stores control information for determining whether the PMOS substrate bias voltage (Vbp) set to be higher in level than the first operating voltage (Vdd) is supplied to the N well and the NMOS substrate bias voltage (Vbn) set to be lower in level than the second operating voltage (Vss) is supplied to the P well (refer to FIG. 13).

In a semiconductor integrated circuit (Chip) according to further another specific embodiment, the PMOS substrate bias voltage (Vbp) supplied to the N well is forwardly biased with respect to the first operating voltage (Vdd) supplied to the source of the PMOS of the CMOS circuit. The NMOS substrate bias voltage (Vbn) supplied to the P well is forwardly biased with respect to the second operating voltage (Vss) supplied to the source of the NMOS of the CMOS circuit. The supply of the PMOS substrate bias voltage (Vbp) set to be lower in level than the first operating voltage (Vdd) to the N well controls the PMOS (Qp01, Qp02 and Qp03) with the N well (N_Well) at a low threshold voltage and high leak current. The supply of the NMOS substrate bias voltage (Vbn) set to be higher in level than the second operating voltage (Vss) to the P well controls the NMOS (Qn01, Qn02 and Qn03) with the P well (P_Well) at a low threshold voltage and high leak current (refer to FIGS. 20A and 20B).

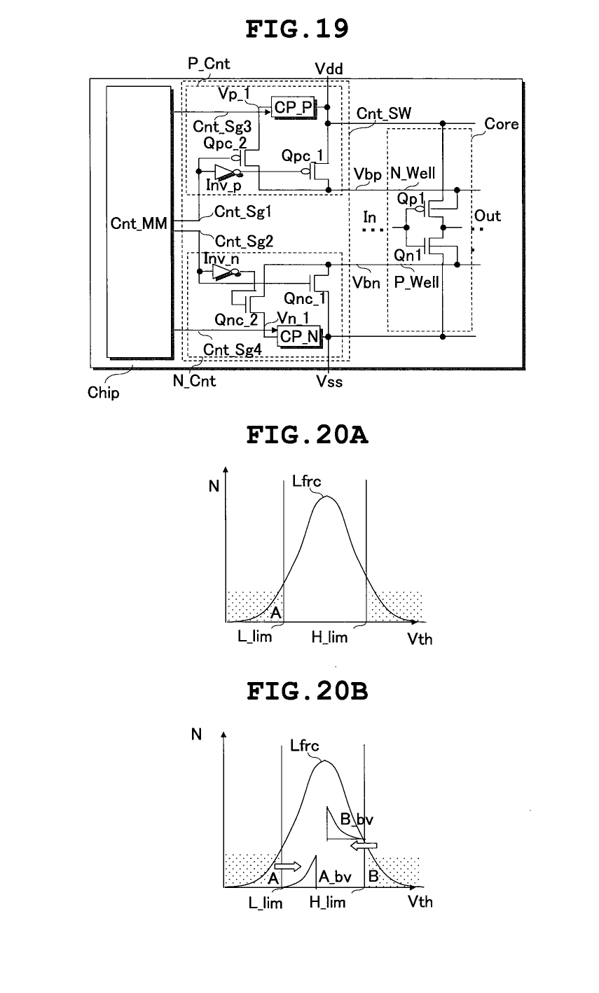

A semiconductor integrated circuit (Chip) according to another specific embodiment includes a control memory (Cnt_MM) which stores control information for determining whether the PMOS substrate bias voltage (Vbp) set to be lower in level than the first operating voltage (Vdd) is supplied to the N well and the NMOS substrate bias voltage (Vbn) set to be higher in level than the second operating voltage (Vss) is supplied to the P well (refer to FIG. 19).

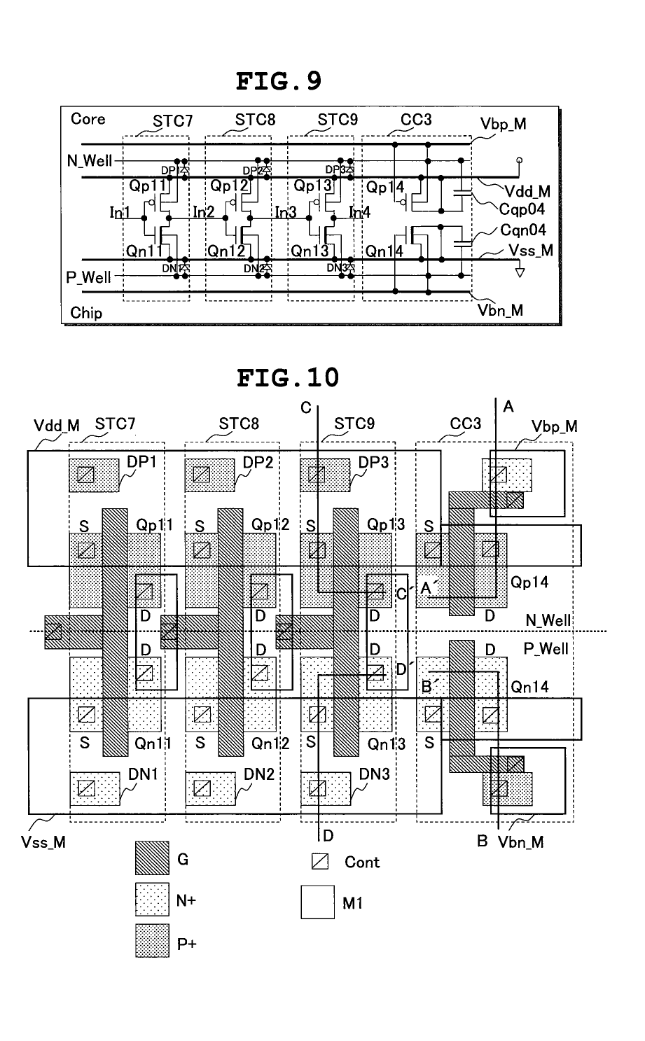

In a semiconductor integrated circuit (Chip) according to further another specific embodiment, the CMOS circuit includes a P-type high impurity density region (DP1, DP2 and DP3) with the N well (N-Well) and N-type high impurity density region (DN1, DN2 and DN3) with the P well (P-Well). A first diode (DP1, DP2 and DP3) including the P-type high impurity density region and the N well (N_Well) is coupled between the source and the N well of the PMOS of the CMOS circuit. A second diode (DN1, DN2 and DN3) including the N-type high impurity density region and the P well (P_Well) is coupled between the source and the P well of the NMOS of the CMOS circuit (FIGS. 9, 10, 11 and 12).

In a semiconductor integrated circuit (Chip) according to further another specific embodiment, the PMOSs of the CMOS circuit are those with an SOI structure. The NMOSs of the CMOS circuit are those with an SOI structure. The source and the drain of the PMOSs and of NMOSs are formed in silicon over an insulating film with the SOI structure. The N well (N_Well) of the PMOSs and the P well (P_Well) of the NMOSs are formed in a silicon substrate (P_Sub) under the insulating film with the SOI structure (FIG. 22).

For this reason, according to the further another specific embodiment, capacity can be decreased between the drain and the well, which provides a semiconductor integrated circuit with a high speed and a low power consumption.

[2] A semiconductor integrated circuit from another point of view includes the MOS circuit (ST1, ST2 and ST3) processing an input signal (In1) and the additional capacitance circuit (CC1) produced in the same production process as the MOS circuit. The MOS circuit and the additional capacitance circuit include the MOS (Qn01, Qn02 and Qn03) and the additional MOS (Qn04) with substrate (P_Well). The sources of the MOS of the MOS circuit and the additional MOS of the additional capacitance circuit are electrically coupled to the first operating voltage wiring (Vss_M). The substrate (P_Well) can be supplied with the MOS substrate bias voltage (Vbn). The gate electrode (G) of the additional MOS (Qn04) of the additional capacitance circuit (CC1) is electrically coupled to the substrate (P_Well) (FIGS. 1, 2 and 3).

For that reason, according to the embodiment, the parasitic capacitance (Cqn04) of gate of the additional MOS in the additional capacitance circuit is coupled between the first operating voltage wiring and the substrate. This transmits charging and discharging noise on the first operating voltage wiring to the MOS substrate bias voltage through the parasitic capacitance of gate of the additional MOS. As a result, it is enabled to reduce the fluctuation of the signal delay in a signal processing resulting from a charging and discharging current produced by signal processing in the active mode due to the use of the substrate bias technique in the active mode (refer to FIG. 4).

In a preferable semiconductor integrated circuit (Chip), the source-gate overlap capacitance between the source (S) and the gate electrode (G) of the additional MOS (Qn04) of the additional capacitance circuit (CC1) and the source-substrate junction capacitance between the source (S) and the substrate (P_well) of the additional MOS (Qn04) of the additional capacitance circuit (CC1) are coupled at least in parallel between the first operating voltage wiring (Vss_M) and the P well (P_Well).

In a more preferable semiconductor integrated circuit (Chip) the source (S) of the additional MOS (Qn04) of the additional capacitance circuit (CC1) is electrically coupled to the drain (D) thereof. The drain-gate overlap capacitance between the drain (D) and the gate electrode (G) of the additional MOS (Qn04) of the additional capacitance circuit (CC1) and the drain-substrate junction capacitance between the drain (D) and the substrate (P_well) of the additional MOS (Qn04) of the additional capacitance circuit (CC1) are further coupled in parallel between the first operating voltage wiring (Vss_M) and the substrate (P_Well).

A further more preferable semiconductor integrated circuit (Chip) includes a voltage generating unit (CP_N) for generating the MOS substrate bias voltage (Vbn) from the first operating voltage (Vss) supplied to the first operating voltage wiring (Vss_M) (refer to FIG. 5).

In a semiconductor integrated circuit (Chip) according to one specific embodiment, the MOS substrate bias voltage (Vbn) supplied to the substrate is reversely biased with respect to the first operating voltage (Vss) supplied to the source of the MOS of the MOS circuit. The supply of the MOS substrate bias voltage (Vbn) set to be lower in level than the first operating voltage (Vss) to the substrate controls the MOS (Qn01, Qn02 and Qn03) formed in the substrate (P_Well) at a high threshold voltage and a low leak current (refer to FIGS. 16A and 16B).

A semiconductor integrated circuit (Chip) according to another specific embodiment includes a control memory (Cnt_MM) which stores control information for determining whether the MOS substrate bias voltage (Vbn) set to be lower in level than the first operating voltage (Vss) is supplied to the substrate (refer to FIG. 13).

In a semiconductor integrated circuit (Chip) according to further another specific embodiment, the MOS substrate bias voltage (Vbn) supplied to the substrate is forwardly biased with respect to the first operating voltage (Vss) supplied to the source of the MOS of the MOS circuit. The supply of the MOS substrate bias voltage (Vbn) set to be higher in level than the first operating voltage (Vss) to the substrate controls the MOS (Qn01, Qn02 and Qn03) formed in the substrate (P_Well) at a low threshold voltage and a high leak current (refer to FIGS. 20A and 20B).

A semiconductor integrated circuit (Chip) according to another specific embodiment includes a control memory (Cnt_MM) which stores control information for determining whether the MOS substrate bias voltage (Vbn) set to be higher in level than the first operating voltage (Vss) is supplied to the substrate (refer to FIG. 19).

In a semiconductor integrated circuit (Chip) according to further another specific embodiment, the MOS circuit includes a high impurity density region (DN1, DN2 and DN3) formed in the substrate (P-Well). A diode (DN1, DN2 and DN3) including the high impurity density region and the substrate (P-Well) is coupled between the source and the substrate of the MOS of the CMOS circuit (FIGS. 9, 10, 11 and 12).

In a semiconductor integrated circuit (Chip) according to further another specific embodiment, the MOSs of the MOS circuit are those with an SOI structure. The source and the drain of the MOSs are formed in silicon over an insulating film with the SOI structure. The well (P_Well) of the MOSs is formed in the silicon substrate (P_Sub) under the insulating film with the SOI structure (FIG. 22).

For this reason, according to the further another specific embodiment, capacity can be decreased between the drain and the well, which provides a semiconductor integrated circuit with a high speed and a low power consumption.

### Description of Embodiments

The embodiments are described below in further detail.

### [Configuration of the Semiconductor Integrated Circuit]

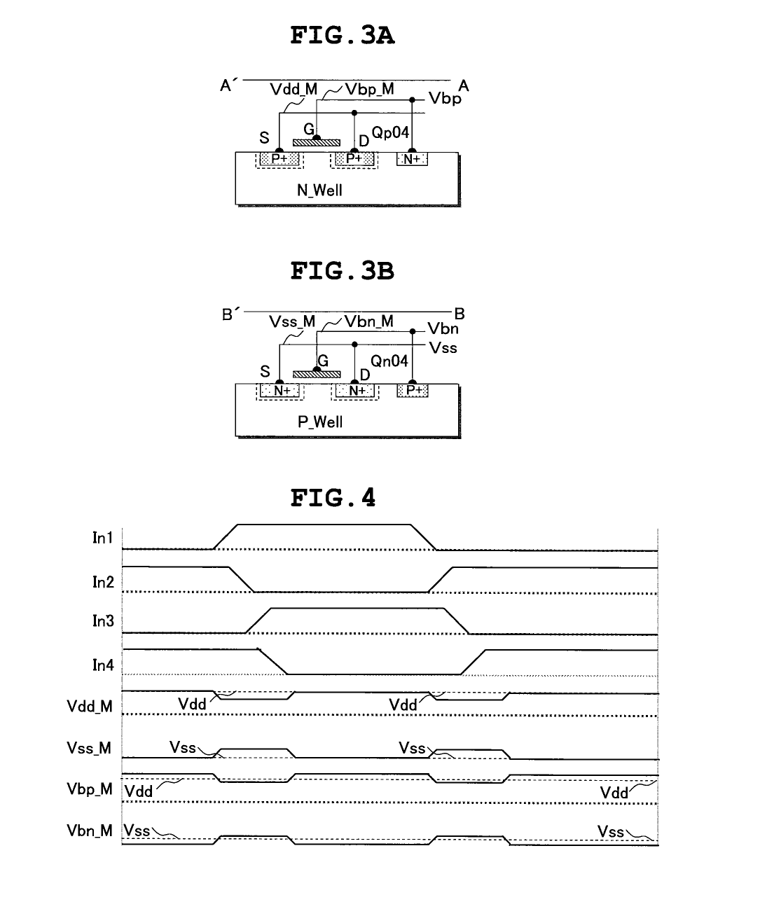

FIG. 1 is a circuit diagram illustrating a semiconductor integrated circuit according to one embodiment of the present invention. The core of the semiconductor integrated circuit in FIG. 1 includes standard cells STC1, STC2 and STC3 being inverter circuits and an additional capacitance cell CC1 to which gate capacitances Cqp04 and Cqn04 are added. FIG. 2 is a layout illustrating the device planar structure of the semiconductor integrated circuit in FIG. 1. FIGS. 3A and 3B are cross sections of the essential part of FIG. 2.

### [Configuration of Standard Cell]

The standard cell STC1 as an inverter of the first stage includes a P-channel MOS transistor Qp01 and an N-channel MOS transistor Qn01. An input signal In1 is supplied to the gates of the P-channel MOS transistor Qp01 and the N-channel MOS transistor Qn01. The drain electrodes of the P-channel MOS transistor Qp01 and the N-channel MOS transistor Qn01 provide output signals which are input signals In1 to the standard cell STC2 of the next stage. The source electrode of the P-channel MOS transistor Qp01 is coupled to the power supply wiring Vdd_M to be supplied with the power supply voltage Vdd. The source electrode of the N-channel MOS transistor Qn01 is coupled to the ground wiring Vss_M to be supplied with the ground voltage Vss. The N well N Well of the P-channel MOS transistor Qp01 is coupled to the PMOS substrate bias wiring Vbp_M to be supplied with the PMOS substrate bias voltage Vbp. The P well P_Well of the N-channel MOS transistor Qn01 is coupled to the NMOS substrate bias wiring Vbn_M to be supplied with the NMOS substrate bias voltage Vbn.

The standard cell STC2 at the second stage and the standard cell STC3 at the third stage also include a P-channel MOS transistor Qp02 and an N-channel MOS transistor Qn02, and a P-channel MOS transistor Qp03 and an N-channel MOS transistor Qn03 respectively, as is the case with the standard cell STC1 at the first stage.

### [Configuration of Additional Capacitance Cell]

The additional capacitance cell CC1 includes a P-channel MOS transistor Qp04 and an N-channel MOS transistor Qn04. The gate electrode of the P-channel MOS transistor Qp04 is coupled to the PMOS substrate bias wiring Vbp_M to be supplied with the PMOS substrate bias voltage Vbp. The gate electrode of the N-channel MOS transistor Qn04 is coupled to the NMOS substrate bias wiring Vbn_M to be supplied with the NMOS substrate bias voltage Vbn. The source and the drain electrode of the P-channel MOS transistor Qp04 are coupled to the power supply wiring Vdd_M to be supplied with the power supply voltage Vdd. The source and the drain electrode of the N-channel MOS transistor Qn04 are coupled to the ground wiring Vss_M to be supplied with the ground voltage Vss.

As a result, a large gate capacitance Cpq04 of the PMOS Qp04 of the additional capacitance cell CC1 is coupled between the power supply wiring Vdd_M coupled to the source electrodes of the PMOSs Qp01, Qp02 and Qp03 of the standard cells STC1, STC2 and STC3 and the PMOS substrate bias wiring Vbp_M coupled to the N well N_Well of the PMOSs Qp01, Qp02 and Qp03. In addition, a large gate capacitance Cpn04 of the NMOS Qn04 of the additional capacitance cell CC1 is coupled between the ground wiring Vss_M coupled to the source electrodes of the NMOSs Qn01, Qn02 and Qn03 of the standard cells STC1, STC2 and STC3 and the NMOS substrate bias wiring Vbn_M coupled to the P well P_Well of the NMOSs Qn01, Qn02 and Qn03.

### [Substrate Bias Voltage]

The PMOS substrate bias voltage Vbp supplied to the N well N_Well of the PMOSs Qp01, Qp02 and Qp03 is reversely biased with respect to the power supply voltage Vdd of the power supply wiring Vdd_M supplied to P-type source electrode of the PMOSs Qp01, Qp02 and Qp03 of the standard cells STC1, STC2 and STC3. That is to say, the PMOS substrate bias voltage Vbp supplied to the N well N_Well of the PMOSs Qp01, Qp02 and Qp03 is set to be higher in level than the power supply voltage Vdd supplied to P-type source electrode of the PMOSs Qp01, Qp02 and Qp03. As a result, the PMOSs Qp01, Qp02 and Qp03 of the standard cells STC1, STC2 and STC3 are controlled at a high threshold voltage and a low leak current. The supply of the voltage being on the same level such as, for example, the power supply voltage Vdd to the P-type source electrodes and the N well N_Well of the PMOSs Qp01, Qp02 and Qp03 causes a reverse-bias substrate bias voltage not to be applied to the PMOSs Qp01, Qp02 and Qp03. In this state, the PMOSs Qp01, Qp02 and Qp03 of the standard cells STC1, STC2 and STC3 are in the state of a low threshold voltage and a high leak current.

The NMOS substrate bias voltage Vbn supplied to the P well P_Well of the NMOSs Qn01, Qn02 and Qn03 is reversely biased with respect to the ground voltage Vss of the ground wiring Vss_M supplied to N-type source electrode of the NMOSs Qn01, Qn02 and Qn03 of the standard cells STC1, STC2 and STC3. That is to say, the NMOS substrate bias voltage Vbn supplied to the P well P_Well of the NMOSs Qn01, Qn02 and Qn03 is set to be lower in level than the ground voltage Vss supplied to the N-type source electrode of the NMOSs Qn01, Qn02 and Qn03. As a result, the NMOSs Qn01, Qn02 and Qn03 of the standard cells STC1, STC2 and STC3 are controlled at a high threshold voltage and a low leak current. The supply of the voltage being on the same level such as, for example, the ground voltage Vss to the N-type source electrodes and the P well P_well of the NMOSs Qn01, Qn02 and Qn03 causes a reverse-bias substrate bias voltage not to be applied to the NMOSs Qn01, Qn02 and Qn03. In this state, the NMOSs Qn01, Qn02 and Qn03 of the standard cells STC1, STC2 and STC3 are in the state of a low threshold voltage and a high leak current.

### [Planar Layout and Cross Section Structure]

FIG. 2 is a layout illustrating the device planar structure of the semiconductor integrated circuit in FIG. 1. The PMOSs Qp01, Qp02 and Qp03 of the standard cells STC1, STC2 and STC3 include a gate electrode G formed of a polycrystalline silicon layer, an N well N_Well, a P-type high impurity density source region and a P-type high impurity density drain region. The PMOS Qn04 of the additional capacitance cell CC1 also includes a gate electrode G formed of a polycrystalline silicon layer, an N well N_Well, a P-type high impurity density source region and a P-type high impurity density drain region. The N well N_Well of the PMOSs Qp01, Qp02, Qp03 and Qp04 is coupled to the PMOS substrate bias wiring Vbp_M formed of a first layer wiring M1 through a contact hole “Cont”. The P-type high impurity density source regions S of the PMOSs Qp01, Qp02, Qp03 and Qp04 are coupled to the power supply wiring Vdd_M formed of the first layer wiring M1 through the contact hole “Cont”. The NMOSs Qn01, Qn02 and Qn03 of the standard cells STC1, STC2 and STC3 include a gate electrode G formed of the polycrystalline silicon layer, a P well P_Well, an N-type high impurity density source region and an N-type high impurity density drain region. The NMOS Qn04 of the additional capacitance cell CC1 also includes a gate electrode G formed by polycrystalline silicon layer, a P well P_Well, an N-type high impurity density source region and an N-type high impurity density drain region. The P well P_Well of the NMOSs Qn01, Qn02, Qn03 and Qn04 is coupled to the NMOS substrate bias wiring Vbn_M formed of the first layer wiring M1 through the contact hole “Cont”. The N-type high impurity density source regions S of the NMOSs Qn01, Qn02, Qn03 and Qn04 are coupled to the ground Vss_M formed of the first layer wiring M1 through the contact hole “Cont”. The gate electrode G and the N well N_Well of the PMOS Qp04 of the additional capacitance cell CC1 are coupled to the PMOS substrate bias wiring Vbp_M formed of the first layer wiring M1. The P-type high impurity density source S and the P-type high impurity density drain region D of the PMOS Qp04 of the additional capacitance cell CC1 are coupled to the power supply wiring Vdd_M formed of the first layer wiring M1. FIG. 3A is a cross section taken along broken the line A-A′ of the PMOS Qp04 of the additional capacitance cell CC1. As illustrated in FIG. 3A, the overlap capacitance between the gate electrode G and the drain electrode D of the PMOS Qp04 of the additional capacitance cell CC1 and the overlap capacitance between the gate electrode G and the source region S form one part of the large gate capacitance Cqp04 of the PMOS Qp04 of the additional capacitance cell CC1. The PN junction between the P-type drain region D and the N well N_Well of the PMOS Qp04 of the additional capacitance cell CC1 and the PN junction between the P-type source region S and the N well N_Well of the PMOS Qp04 form the other part of the large gate capacitance Cqp04 of the PMOS Qp04 of the additional capacitance cell CC1. The gate electrode G and the P well P_Well of the NMOS Qn04 of the additional capacitance cell CC1 are coupled to the NMOS substrate bias wiring Vbn_M formed of the first layer wiring M1. The N-type high impurity density source region S and the N-type high impurity density drain region D of the NMOS Qn04 of the additional capacitance cell CC1 are coupled to the ground wiring Vss_M formed of the first layer wiring M1. FIG. 3B is a cross section taken along the broken line B-B′ of the NMOS Qn04 of the additional capacitance cell CC1. As illustrated in FIG. 3B, the overlap capacitance between the gate electrode G and the drain electrode D of the NMOS Qn04 of the additional capacitance cell CC1 and the overlap capacitance between the gate electrode G and the source region S form one part of the large gate capacitance Cqn04 of the NMOS Qn04 of the additional capacitance cell CC1. The PN junction between the N-type drain region D and the N well N_Well of the PMOS Qn04 of the additional capacitance cell CC1 and the PN junction between the N-type source region S and the P well P_Well of the PMOS Qp04 form the other part of the large gate capacitance Cqn04 of the NMOS Qn04 of the additional capacitance cell CC1.

### [Operation of Active Mode]

FIG. 4 is wave forms describing the operation of an active mode in the semiconductor integrated circuit illustrated in FIGS. 1, 2 and 3. As illustrated in FIG. 4, in the standard cells STC1, STC2 and STC3, the PMOS substrate bias voltage Vbp of a reverse bias is applied to the PMOS Qp01, Qp02 and Qp03. The NMOS substrate bias voltage Vbn of a reverse bias is applied also to the NMOS Qn01, Qn02 and Qn03. As illustrated in the figure, it is presumed that the input signal In1 of the standard cell STC1 of the inverter at the first stage, the input signal In2 of the standard cell STC2 of the inverter at the second stage and the input signal In3 of the standard cell STC3 of the inverter at the third stage change from “low level” to “high level” or from “high level” to “low level”. Charging and discharging current of load capacities of the output terminals of the standard cells STC1, STC2 and STC3 flows out of the power supply wiring Vdd_M and flows into the ground wiring Vss_M during the period in which these input signals change, so that the power supply voltage Vdd of the power supply wiring Vdd_M reduces in level and the ground voltage Vss of the ground wiring Vss_M increases in level.

When the large gate capacity Cqp04 of the PMOS Qp04 of the additional capacitance cell CC1 is not coupled between the power supply wiring Vdd_M and the PMOS substrate bias wiring Vbp_M, the output voltage of a PMOS substrate bias generator maintains the voltage of the PMOS substrate bias wiring Vbp_M substantially constant even if the power supply voltage Vdd of the power supply wiring Vdd_M varies in level. As a result, the threshold voltage Vth(P) of PMOSs Qp01, Qp02 and Qp03 of the standard cells STC1, STC2 and STC3 lowers and also the various electric characteristics of the standard cells STC1, STC2 and STC3 vary. When the large gate capacity Cqn04 of the NMOS Qn04 of the additional capacitance cell CC1 is not coupled between the ground wiring Vss_M and the NMOS substrate bias wiring Vbn_M, the output voltage of an NMOS substrate bias generator maintains the voltage of the NMOS substrate bias wiring Vbn_M substantially constant even if the ground voltage Vss of the ground wiring Vss_M varies in level. As a result, the threshold voltage Vth(N) of the NMOSs Qn01, Qn02 and Qn03 of the standard cells STC1, STC2 and STC3 lowers and also the various electric characteristics of the standard cells STC1, STC2 and STC3 vary.

### [Effects of Additional Capacitance Cell]

On the other hand, in the semiconductor integrated circuit according to one embodiment of the present invention illustrated in FIGS. 1, 2 and 3, the large gate capacity Cqp04 of the PMOS Qp04 of the additional capacitance cell CC1 is coupled between the power supply wiring Vdd_M and the PMOS substrate bias wiring Vbp_M and the large gate capacity Cqn04 of the NMOS Qn04 of the additional capacitance cell CC1 is coupled between the ground wiring Vss_M and the NMOS substrate bias wiring Vbn_M. As a result, a decrease in the power supply voltage Vdd of the power supply wiring Vdd_M decreases also the voltage of the PMOS substrate bias wiring Vbp_M. An increase in the ground voltage Vss of the ground wiring Vss_M increases also the voltage of the NMOS substrate bias wiring Vbn_M. For this reason, a decrease in the threshold voltage Vth(P) of the PMOSs Qp01, Qp02 and Qp03 of the standard cells STC1, STC2 and STC3 and the threshold voltage Vth(N) of the NMOSs Qn01, Qn02 and Qn03 is reduced. A variation in the various electric characteristics of the standard cells STC1, STC2 and STC3 is also reduced.

### [System LSI Including Core]

FIG. 5 is a circuit diagram of a system LSI being the semiconductor integrated circuit according to one embodiment of the present invention. A logic core “Core” in FIG. 5 includes the standard cells STC1, STC2 and STC3 and the additional capacitance cell CC1 to which the gate capacitances Cqp04 and Cqn04 are added, illustrated in the semiconductor integrated circuit in FIG. 1. The system LSI further includes a power supply pad Vdd_Pad, a ground pad Vss_Pad, a PMOS control unit P_Cnt and an NMOS control unit N-Cnt.

The power supply wiring Vdd_M is coupled to the power supply pad Vdd_Pad to be supplied with the power supply voltage Vdd, and the ground wiring Vss_M is coupled to the ground pad Vss_Pad to be supplied with the ground voltage Vss. The PMOS substrate bias wiring Vbp_M is connected to the positive voltage generating unit CP_P of the PMOS control unit P_Cnt and the drain electrode of the PMOSs Qpc11 and Qpc1n. The positive voltage generating unit CP_P is formed of, for example, a charge pump circuit and generates a voltage Vdd+Δ higher than the power supply voltage Vdd from the power supply voltage Vdd. A control switch circuit Cnt_SW_p is coupled to the gates of the PMOSs Qpc11 and Qpc1n. The NMOS substrate bias wiring Vbn_M is connected to the negative voltage generating unit CP_N of the NMOS control unit N_Cnt and the drain electrode of the NMOSs Qnc11 and Qnc1n. The negative voltage generating unit CP_N is formed of, for example, a charge pump circuit and generates a voltage Vss−Δ lower than the ground voltage Vss from the ground voltage Vss. A control switch circuit Cnt_SW_n is coupled to the gates of the NMOSs Qnc11 and Qnc1n.

When the power supply voltage Vdd is supplied to the PMOS substrate bias wiring Vbp_M, the positive voltage generating unit CP_P is turned off and the PMOSs Qpc11 and Qpc1n are turned on to supply the power supply voltage Vdd to the PMOS substrate bias wiring Vbp_M from the power supply pad Vdd_Pad. In addition, when the voltage Vdd+Δ higher than the power supply voltage Vdd is supplied to the PMOS substrate bias wiring Vbp_M, the positive voltage generating unit CP_P is turned on and the PMOSs Qpc11 and Qpc1n are turned off. When the ground voltage Vss is supplied to the NMOS substrate bias wiring Vbn_M, the negative voltage generating unit CP_N is turned off and the NMOSs Qnc11 and Qnc1n are turned on to supply the ground voltage Vss to the NMOS substrate bias wiring Vbn_M from the ground pad Vss_Pad. In addition, when the voltage Vss−Δ lower than the ground voltage Vss is supplied to the NMOS substrate bias wiring Vbn_M, the negative voltage generating unit CP_N is turned on and the NMOSs Qnc11 and Qnc1n are turned off.

### Semiconductor Integrated Circuit According to Another Embodiment

### [Elimination of High Impurity Density Region in Well of Standard Cell]

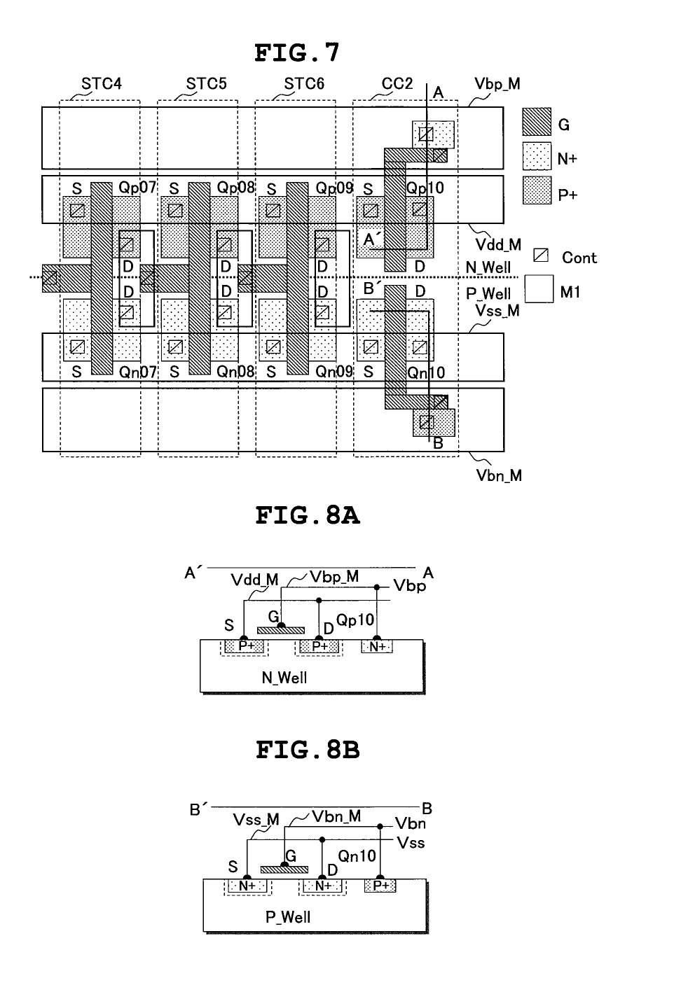

FIG. 6 is a circuit diagram illustrating the semiconductor integrated circuit according to another embodiment of the present invention. FIG. 7 is a layout illustrating the device planar structure of the semiconductor integrated circuit in FIG. 6. FIGS. 8A and 8B are cross sections of the essential part of FIG. 7.

The semiconductor integrated circuit illustrated in FIGS. 6 and 7 is different from that illustrated in FIGS. 1 and 2 in the following points.

In the semiconductor integrated circuit illustrated in FIGS. 1 and 2, the N-type high impurity density region N+ with the contact hole “Cont” is formed in the N well N_Well of the PMOSs Qp01, Qp02 and Qp03 of the standard cells STC1, STC2 and STC3 to electrically couple the N well N_Well of the PMOSs Qp01, Qp02 and Qp03 of the standard cells STC1, STC2 and STC3 to the PMOS substrate bias wiring Vbp_M. In addition, in the semiconductor integrated circuit illustrated in FIGS. 1 and 2, the P-type high impurity density region P+ with the contact hole “Cont” is formed in the P well P_Well of the NMOSs Qn01, Qn02 and Qn03 of the standard cells STC1, STC2 and STC3 to electrically couple the P well P_Well of the NMOSs Qn01, Qn02 and Qn03 of the standard cells STC1, STC2 and STC3 to the NMOS substrate bias wiring Vbn_M.

On the other hand, in the semiconductor integrated circuit illustrated in FIGS. 6 and 7, the N-type high impurity density region N+ is eliminated from the N well N_Well of the PMOSs Qp07, Qp08 and Qp09 of the standard cells STC1, STC2 and STC3. The P-type high impurity density region P+ is eliminated from the P well P_Well of the NMOSs Qn07, Qn08 and Qn09 of the standard cells STC1, STC2 and STC3. That is to say, in FIGS. 6 and 7, the N-type high impurity density region N+ with the contact hole “Cont” is formed in the N well N_Well of the PMOS Qp10 of the additional capacitance cell CC1 to electrically couple the N well N_Well of the PMOSs Qp07, Qp08 and Qp09 of the standard cells STC1, STC2 and STC3 to the PMOS substrate bias wiring Vbp_M.

FIG. 8A is a cross section taken along the broken line A-A′ of the PMOS Qp10 of the additional capacitance cell CC1 in FIG. 7. As illustrated in FIG. 8A, the N-type high impurity density region N+ is formed in the N well N_Well of the PMOS Qp10 of the additional capacitance cell CC1 and electrically coupled to the PMOS substrate bias wiring Vbp_M. In addition, the N well N_Well of the PMOS Qp10 of the additional capacitance cell CC1 is integrally formed with the N well N_Well of the PMOSs Qp07, Qp08 and Qp09 of the standard cells STC1, STC2 and STC3. For this reason, the N well N_Well of the PMOSs Qp07, Qp08 and Qp09 of the standard cells STC1, STC2 and STC3 can be electrically coupled to the PMOS substrate bias wiring Vbp_M. Furthermore, FIG. 8B is a cross section taken along the broken line B-B′ of the NMOS Qn10 of the additional capacitance cell CC1 in FIG. 7. As illustrated in FIG. 8B, the P-type high impurity density region P+ is formed in the P well P_Well of the NMOS Qn10 of the additional capacitance cell CC1 and electrically coupled to the NMOS substrate bias wiring Vbn_M. In addition, the P well P_Well of the NMOS Qn10 of the additional capacitance cell CC1 is integrally formed with the P well P_Well of the NMOSs Qn07, Qn08 and Qn09 of the standard cells STC1, STC2 and STC3. For this reason, the P well P_Well of the NMOSs Qn07, Qn08 and Qn09 of the standard cells STC1, STC2 and STC3 can be electrically coupled to the NMOS substrate bias wiring Vbn_M.

### [Addition of Parasitic Diode in Well of Standard Cell]

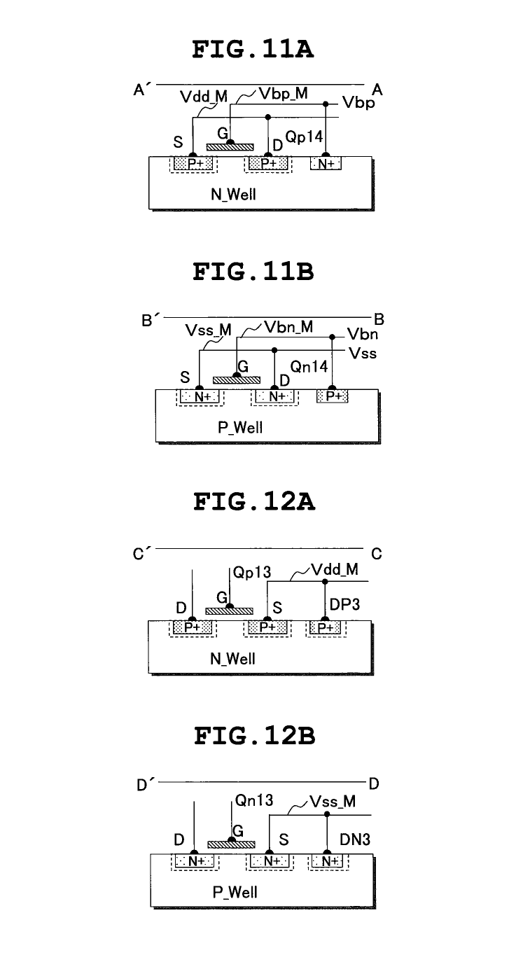

FIG. 9 is a circuit diagram illustrating the semiconductor integrated circuit according to further another embodiment of the present invention. FIG. 10 is a layout illustrating the device planar structure of the semiconductor integrated circuit in FIG. 9. FIGS. 11A and 11B are cross sections of the essential part of FIG. 10. FIGS. 12A and 12B are also cross sections of the essential part of FIG. 10.

The semiconductor integrated circuit illustrated in FIGS. 9 and 10 is different from that illustrated in FIGS. 1 and 2 in the following points.

In the semiconductor integrated circuit illustrated in FIGS. 1 and 2, the N-type high impurity density region N+ with the contact hole “Cont” is formed in the N well N_Well of the PMOSs Qp01, Qp02 and Qp03 of the standard cells STC1, STC2 and STC3 to electrically couple the N well N_Well of the PMOSs Qp01, Qp02 and Qp03 of the standard cells STC1, STC2 and STC3 to the PMOS substrate bias wiring Vbp_M. In addition, in the semiconductor integrated circuit illustrated in FIGS. 1 and 2, the P-type high impurity density region P+ with the contact hole “Cont” is formed in the P well P_Well of the NMOSs Qn01, Qn02 and Qn03 of the standard cells STC1, STC2 and STC3 to electrically couple the P well P_Well of the NMOSs Qn01, Qn02 and Qn03 of the standard cells STC1, STC2 and STC3 to the NMOS substrate bias wiring Vbn_M.

On the other hand, in the semiconductor integrated circuit illustrated in FIGS. 9 and 10, the P-type high impurity density regions DP1, DP2 and DP3 are formed in the N well N_Well of the PMOSs Qp11, Qp12 and Qp13 of the standard cells STC1, STC2 and STC3. The P-type high impurity density regions DP1, DP2 and DP3 of the standard cells STC1, STC2 and STC3 and the P-type high impurity density source region S of the PMOS Qp11, Qp12 and Qp13 are coupled to the power supply wiring Vdd_M formed of the first layer wiring M1 through the contact hole “Cont”. FIG. 12A is a cross section taken along the broken line C-C′ of the PMOS Qp13 of the standard cell STC3 in FIG. 10. As illustrated in FIG. 12A, a P-type high impurity density region DP3 is formed in the N well N_Well of the PMOS Qp13 of the standard cell STC3. The P-type high impurity density region DP3 and the P-type high impurity density source region S of the PMOS Qp13 are coupled to the power supply wiring Vdd_M formed of the first layer wiring M1 through the contact hole “Cont”. As a result, as illustrated in FIG. 9, parasitic diodes DP1, DP2 and DP3 are coupled between the P-type high impurity density source regions and the N well N_Well of the PMOSs Qp11, Qp12 and Qp13 of the standard cells STC1, STC2 and STC3.

FIG. 11A is a cross section taken along the broken line A-A′ of the PMOS Qp14 of the additional capacitance cell CC3 in FIG. 10. As illustrated in FIG. 11A, an N-type high impurity density region N+ is formed in the N well N_Well of the PMOS Qp14 of the additional capacitance cell CC1 and electrically coupled to the PMOS substrate bias wiring Vbp_M. In addition, the N well N_Well of the PMOS Qp14 of the additional capacitance cell CC1 is integrally formed with the N wells N_Well of the PMOSs Qp11, Qp12 and Qp13 of the standard cells STC1, STC2 and STC3. Consequently, the N wells N_Well of the PMOSs Qp11, Qp12 and Qp13 of the standard cells STC1, STC2 and STC3 can be electrically coupled to the PMOS substrate bias wiring Vbp_M irrespective of the presence of the parasitic diodes DP1, DP2 and DP3.

In the semiconductor integrated circuit illustrated in FIGS. 9 and 10, the N-type high impurity density regions DN1, DN2 and DN3 are formed in the P well P_Well of the NMOSs Qn11, Qn12 and Qn13 of the standard cells STC1, STC2 and STC3. The N-type high impurity density regions DN1, DN2 and DN3 of the standard cells STC1, STC2 and STC3 and the N-type high impurity density source regions S of the NMOSs Qn11, Qn12 and Qn13 are coupled to the ground wiring Vss_M formed of the first layer wiring M1 through the contact hole “Cont”. FIG. 12B is a cross section taken along the broken line D-D′ of the NMOS Qn13 of the standard cell STC3 in FIG. 10. As illustrated in FIG. 12B, the N-type high impurity density region DN3 is formed in the P well P_Well of the NMOS Qn13 of the standard cell STC3. The N-type high impurity density region DN3 and the N-type high impurity density source region S of the NMOS Qn13 are coupled to the ground wiring Vss_M formed of the first layer wiring M1 through the contact hole “Cont”. As a result, as illustrated in FIG. 9, the parasitic diodes DN1, DN2 and DN3 are coupled between the N-type high impurity density source regions and the P well P_Well of the NMOS Qn11, Qn12 and Qn13 of the standard cells STC1, STC2 and STC3.

FIG. 11B is a cross section taken along the broken line B-B′ of the NMOS Qn14 of the additional capacitance cell CC1 in FIG. 10. As illustrated in FIG. 11B, the P-type high impurity density region P+ is formed in the P well P_Well of the NMOS Qn14 of the additional capacitance cell CC1 and electrically coupled to the NMOS substrate bias wiring Vbn_M. In addition, the P well P_Well of the NMOS Qn14 of the additional capacitance cell CC1 is integrally formed with the P well P_Well of the NMOSs Qn11, Qn12 and Qn13 of the standard cells STC1, STC2 and STC3. Consequently, the P well P_Well of the NMOSs Qn11, Qn12 and Qn13 of the standard cells STC1, STC2 and STC3 can be electrically coupled to the NMOS substrate bias wiring Vbn_M irrespective of the presence of the parasitic diodes DN1, DN2 and DN3.

### [Adjustment of MOS Threshold Voltage by Substrate Bias Voltage]

FIG. 13 is a circuit diagram illustrating a semiconductor integrated circuit compensating the dispersion of threshold voltage of MOS transistors of the standard cells STC1, STC2 and STC3 in the core of FIG. 1.

In the figure, an LSI chip “Chip” as a semiconductor integrated circuit includes a CMOS logic circuit of a core circuit “Core”, a control memory Cnt_MM and a control switch Cnt_SW for compensating the dispersion of characteristics of the core CMOS logic circuit “Core”. The core CMOS logic circuit “Core” includes the PMOS Qp1 whose source is coupled to the power supply voltage Vdd and the NMOS Qn1 whose source is coupled to the ground voltage Vss. The input signal “In” is applied to the gates of the PMOS Qp1 and the NMOS Qn1 and the drains of the PMOS Qp1 and the NMOS Qn1 provides the output signal “Out”. The control switch Cnt_SW includes a PMOS control unit P_Cnt and an NMOS control unit N_Cnt.

The PMOS control unit P_Cnt includes PMOSs Qpc_1 and Qpc_2 and an inverter Inv_p. In the PMOS control unit P_Cnt, the power supply voltage Vdd is applied to the source of the PMOS Qpc_1, and the N well bias voltage Vp_1 higher than the power supply voltage Vdd is applied to the source of the PMOS Qpc_2. The drains of the PMOS Qpc_1 and the PMOS Qpc_2 are coupled to the N well N_Well of the PMOS Qp1 of the core CMOS logic circuit “Core”.

The NMOS control unit N_Cnt includes NMOSs Qnc_1 and Qnc_2 and an inverter Inv_n. In the NMOS control unit N_Cnt, the ground voltage Vss is applied to the source of the NMOS Qnc_1, and the P well bias voltage Vn_l lower than the ground voltage Vss is applied to the source of the NMOS Qnc_2. The drains of the NMOS Qnc_1 and the NMOS Qnc_2 are coupled to the P well P_Well of the NMOS Qn1 of the core CMOS logic circuit “Core”.

An output signal Cnt_Sg of the control memory Cnt_MM is increased in level to turn on the PMOS Qpc_1 of the PMOS control unit P_Cnt and turn on the NMOS Qnc_1 of the NMOS control unit N_Cnt. Then, the power supply voltage Vdd is applied to the N well N_Well of the PMOS Qp1 of the core CMOS logic circuit “Core” as PMOS substrate bias voltage Vbp. The ground voltage Vss is applied to the P well P_Well of the NMOS Qn1 of the core CMOS logic circuit “Core” as NMOS substrate bias voltage Vbn. On the other hand, the power supply voltage Vdd and the ground voltage Vss are applied to the sources of the PMOS Qp1 and the NMOS Qn1 of the core CMOS logic circuit “Core” respectively. For this reason, the power supply voltage Vdd is applied in common to the source and the N well N_Well of the PMOS Qp1 of the core CMOS logic circuit “Core” and the ground voltage Vss is applied in common to the source and the P well P_Well of the NMOS Qn1 of the core CMOS logic circuit “Core”.

An output signal Cnt_Sg of the control memory Cnt_MM is decreased in level to turn on the PMOS Qpc_2 of the PMOS control unit P_Cnt and turn on the NMOS Qnc_2 of the NMOS control unit N_Cnt. Then, the N well bias voltage Vp_1 higher in level than the power supply voltage Vdd is applied to the N well N_Well of the PMOS Qp1 of the core CMOS logic circuit “Core” as PMOS substrate bias voltage Vbp. The P well bias voltage Vn_1 lower in level than the ground voltage Vss is applied to the P well P_Well of the NMOS Qn1 of the core CMOS logic circuit “Core” as NMOS substrate bias voltage Vbn. On the other hand, the power supply voltage Vdd and the ground voltage Vss are applied to the sources of the PMOS Qp1 and the NMOS Qn1 of the core CMOS logic circuit “Core” respectively. For this reason, the higher N well bias voltage Vp_1 applied to the N well N_Well is reversely biased with respect to the power supply voltage Vdd applied to the source of the PMOS Qp1 of the core CMOS logic circuit “Core”. The lower P well bias voltage Vn_1 applied to the P well P_Well is also reversely biased with respect to the ground voltage Vss applied to the source of the NMOS Qn1 of the core CMOS logic circuit “Core”. As a result, both the PMOS Qp1 and NMOS Qn1 of the core CMOS logic circuit “Core” are controlled at the high threshold voltage Vth to enable a leak current to be decreased.

### [Wafer Test and Wafer Process for Measuring Leak Current]

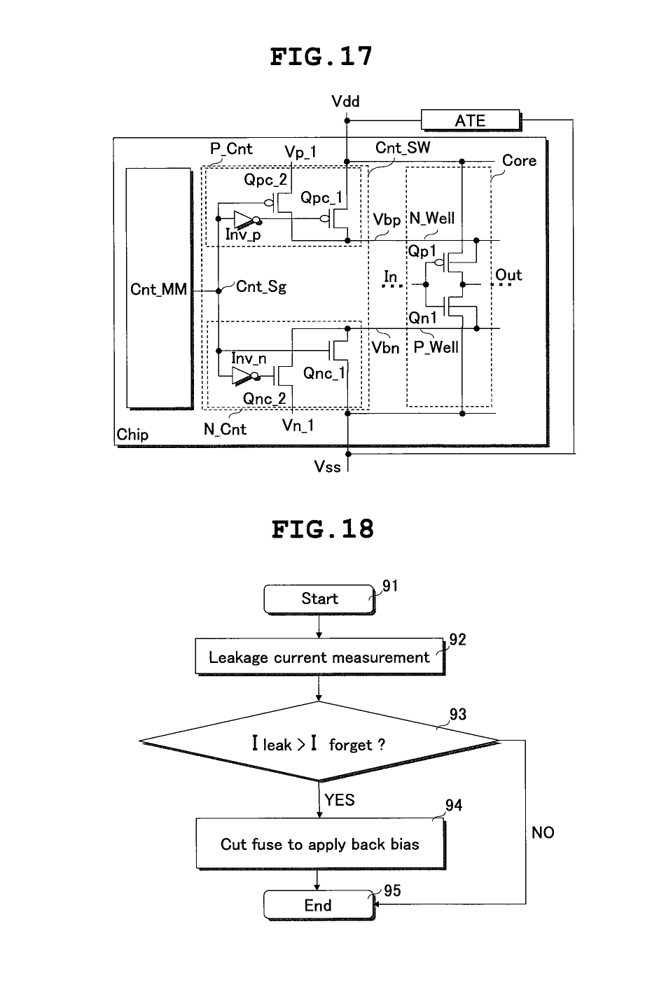

FIG. 17 is a circuit diagram describing wafer test including a large number of LSI chips “Chip” illustrated in FIG. 13. FIG. 18 is a flow chart describing the method of producing the semiconductor integrated circuit including the flow of wafer test and wafer process.

When wafer test starts at step 91 in FIG. 18, the leak current of one LSI chip “Chip” is measured by an external tester ATE illustrated in FIG. 17 coupled in advance to the power supply voltage Vdd and the ground voltage Vss of the LSI chip “Chip” at step 92 where current is measured. At step 93, a determination is made using the external tester ATE as to whether a leak current measured at step 92 is larger than a design target value. If it is determined using the external tester ATE that the leak current measured at step 93 is larger the design target value, it means that the threshold voltage Vth of the MOS transistor of the core CMOS logic circuit “Core” in the chip “Chip” is significantly lower than the design target value. In this case, at step 94, a fuse FS as a nonvolatile memory element of the control memory Cnt_MM is cut to apply the substrate bias so that the threshold voltage Vth of the MOS transistor of the core CMOS logic circuit “Core” is changed from a low threshold voltage Vth to a high threshold voltage Vth. Conversely, if it is determined using the external tester ATE that the leak current measured at step 93 is smaller than the design target value, it means that the threshold voltage Vth of the MOS transistor of the core CMOS logic circuit “Core” in the chip “Chip” is higher than the design target value. In this case, since the threshold voltage Vth of the MOS transistor of the core CMOS logic circuit “Core” does not need to be changed to a high threshold voltage Vth, the process is terminated at step 95. The process proceeds to the step 92 where the leak current of the following LSI chip “Chip” is measured and the step 93 for determination.

When the LSI wafer test including a large number of chips illustrated in FIG. 18 is completed, a fuse FS of each control memory Cnt_MM in a large number of chips of one wafer is in a cut state or not. The operation for the cases where the fuse FS of the control memory Cnt_MM is in a cut state or not is described with reference to the LSI chip “Chip” illustrated in FIG. 13.

### [Control Memory]

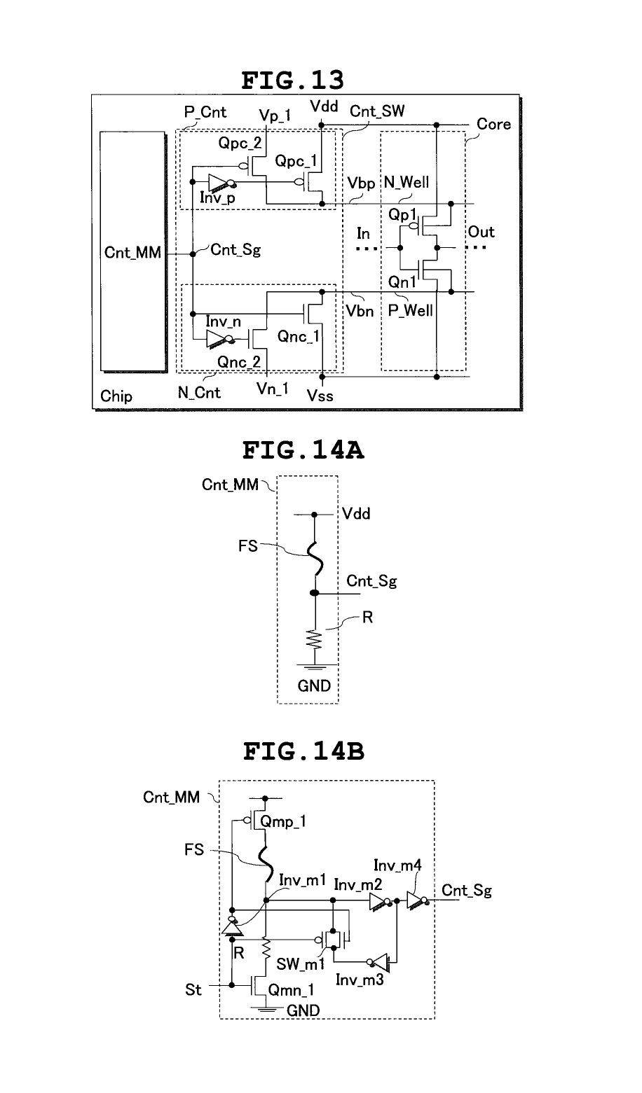

FIGS. 14A and 14B are circuit diagrams illustrating an example of the configuration of a control memory Cnt_MM of an LSI chip “Chip” in FIG. 13. FIG. 14A illustrates a simplest control memory Cnt_MM including a fuse FS and a resistor R coupled in series between the power supply voltage Vdd and the ground voltage GND. FIG. 14B illustrates a slightly complicated control memory Cnt_MM including a PMOS Qmp_1, a fuse FS, a resistor R and an NMOS Qmn_1 coupled in series between the power supply voltage Vdd and the ground voltage GND, four inverters Inv_m1 . . . m4 and a CMOS analog switch SW_m1. When the fuse FS in the control memory Cnt_MM in FIG. 14A is cut at step 94 in FIG. 18, a high power supply voltage Vdd is applied to the fuse FS to blow it. When the fuse FS in the control memory Cnt_MM in FIG. 14B is cut at step 94 in FIG. 18, a high level control signal St and a high power supply voltage Vdd are applied to the fuse FS to blow it. When the fuse FS in the control memory Cnt_MM in FIG. 14A is cut at step 94 in FIG. 18, the output signal Cnt_Sg of the control memory Cnt_MM at the initial period when the following LSI chip “Chip” starts operation is turned into the ground voltage low in level. Conversely, when the fuse FS in the control memory Cnt_MM in FIG. 14A is not cut in the process of FIG. 18, the output signal Cnt_Sg at the initial period when the following LSI chip “Chip” starts operation is turned into the power supply voltage high in level. When the fuse FS in the control memory Cnt_MM in FIG. 14B is cut in the process in FIG. 18, the latch output signal Cnt_Sg of the control memory Cnt_MM at the initial period when operation starts is turned into the ground voltage GND low in level in response to the starting signal St high in level. Conversely, when the fuse FS in the control memory Cnt_MM in FIG. 14B is not cut in the process in FIG. 18, the latch output signal Cnt_Sg at the initial period when operation starts is turned into the power supply voltage Vdd high in level in response to the starting signal St high in level.

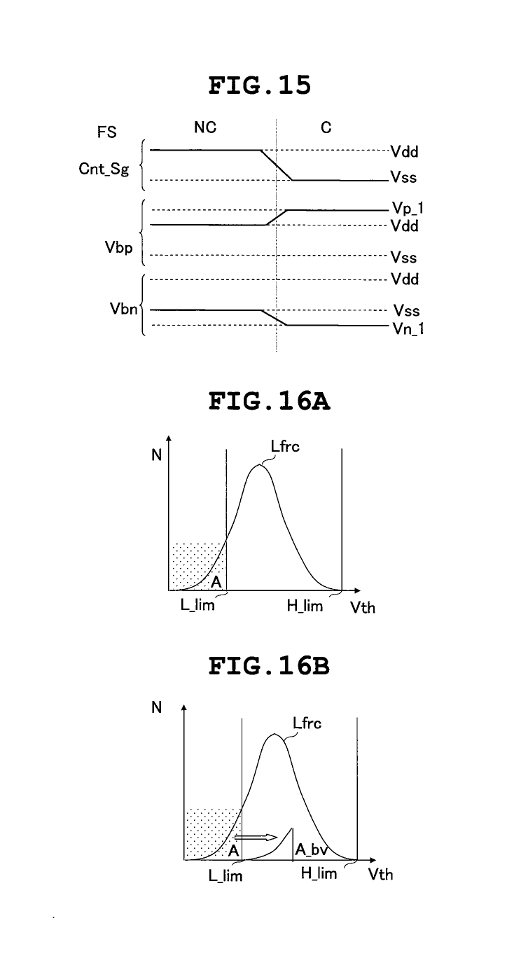

It is presumed that the fuse FS of the control memory Cnt_MM in the LSI chip “Chip” in FIG. 13 is in a non-cut state. Then, the latch output signal Cnt_Sg of the control memory Cnt_MM at the initial period when the LSI chip “Chip” starts operation is turned into the power supply voltage Vdd high in level. First, the PMOS Qpc_2 in the PMOS control unit P_Cnt of the control switch Cnt_SW is turned off, the output of the inverter Inv_p is decreased in level and the PMOS Qpc_1 is turned on. Then, turning on the PMOS Qpc_1 applies the power supply voltage Vdd applied to the source of the PMOS Qpc_1 to the N well N_Well of the PMOS Qp1 of the core CMOS logic circuit “Core”. In addition, the NMOS Qnc_1 in the NMOS control unit N_Cnt of the control switch Cnt_SW is turned on, the output of the inverter Inv_p is decreased in level and the NMOS Qnc_2 is turned off. Then, turning on the PMOS Qnc_1 applies the ground voltage Vss applied to the source of the NMOS Qnc_1 to the P well P_Well of the NMOS Qn1 of the core CMOS logic circuit “Core”. The relationship of voltages of each portion in the semiconductor integrated circuit illustrated in FIG. 13 at this point is shown as a non-cut state NC on the left side in FIG. 15. FIG. 15 is a chart illustrating the relationship of voltages of each portion in the semiconductor integrated circuit illustrated in FIG. 13.

It is presumed that the fuse FS of the control memory Cnt_MM in the LSI chip “Chip” in FIG. 13 is in a cut state. Then, the latch output signal Cnt_Sg of the control memory Cnt_MM at the initial period when the LSI chip “Chip” starts operation is turned into the ground voltage Vss low in level. First, the PMOS Qpc_2 in the PMOS control unit P_Cnt of the control switch Cnt_SW is turned on, the output of the inverter Inv_p is increased in level and the PMOS Qpc_1 is turned off. Then, turning on the PMOS Qpc_2 applies the high N well bias voltage Vp_1 applied to the source of the PMOS Qpc_2 to the N well N_Well of the PMOS Qp1 of the core CMOS logic circuit “Core”. In addition, the NMOS Qnc_1 in the NMOS control unit N_Cnt of the control switch Cnt_SW is turned off, the output of the inverter Inv_n is increased in level and the NMOS Qnc_2 is turned on. Then, turning on the NMOS Qnc_2 applies the low P well bias voltage Vn_1 applied to the source of the NMOS Qnc_2 to the P well P_Well of the NMOS Qn1 of the core CMOS logic circuit “Core”. The relationship of voltages of each portion in the semiconductor integrated circuit illustrated in FIG. 13 at this point is shown as a cut state “C” on the right side in FIG. 15. Thus, the high N well bias voltage Vp_1 is applied to the N well N_Well of the PMOS Qp1 of the core CMOS logic circuit “Core” and the low P well bias voltage Vn_1 is applied to the P well P_Well of the NMOS Qn1 of the core CMOS logic circuit “Core”. As illustrated in FIG. 15, the N well bias voltage Vp_1 of the PMOS Qp1 is set to be higher than the power supply Vdd for the source and the P well bias voltage Vn_1 of the NMOS Qn1 is set to be lower than the power supply Vss for the source. As a result, the threshold voltage of the PMOS Qp1 and the NMOS Qn1 of the core CMOS logic circuit “Core” is changed from a low threshold voltage Vth to a high threshold voltage Vth.

### [Control of Threshold Voltage Vth of MOS LSI]

FIGS. 16A and 16B are graphs describing the distribution of the threshold voltage Vth of a produced MOS LSI. An abscissa in the figure shows the threshold voltage Vth of the MOS LSI, an ordinate in the figure shows the number of chips of MOS LSI and a curve Lfrc shows distribution. A decrease in the threshold voltage Vth of the MOS LSI to the lower limit threshold value L_lim or lower significantly increases a leak current to remarkably increase a consumption current. Conversely, an increase in the threshold voltage Vth of the MOS LSI to the upper limit threshold value H_lim or higher significantly lowers a switching speed to remarkably lower the data processing speed.

For this reason, a group A of the MOS LSI chips whose threshold voltage Vth is not greater than the lower limit threshold value L_lim has been disposed of as a defective before the present invention was made. According to one embodiment of the present invention, the fuses of the group A of the MOS LSI chips are cut at step 94 in FIG. 18. This changes the threshold voltage of the PMOS Qp1 and the NMOS Qn1 of the core CMOS logic circuit “Core” from a low threshold voltage Vth to a high threshold voltage Vth at the initial period when the LSI chip “Chip” starts operation. As illustrated in FIG. 16B, the previous chip group A is changed to a reproduced chip group A_bv. As a result, an average threshold voltage Vth of all the PMOSs and the NMOSs in the core CMOS logic circuit of the MOS LSI chip exceeds the lower threshold value L_Lim, enabling the leak current of the entire chip to be decreased. Accordingly, adding the control memory Cnt_MM and the control switch Cnt_SW occupying a small area to the core CMOS logic circuit of a large scale logic occupying a large area in the LSI chip allows producing a MOS LSI with a high yield and a low leak current.

### [Wafer Teat and Wafer Process]

FIG. 19 is a circuit diagram illustrating the semiconductor integrated circuit according to further another embodiment of the present invention. The MOS LSI chip “Chip” illustrated in FIG. 19 is basically different from the MOS LSI chip “Chip” illustrated in FIG. 13 in the following point.

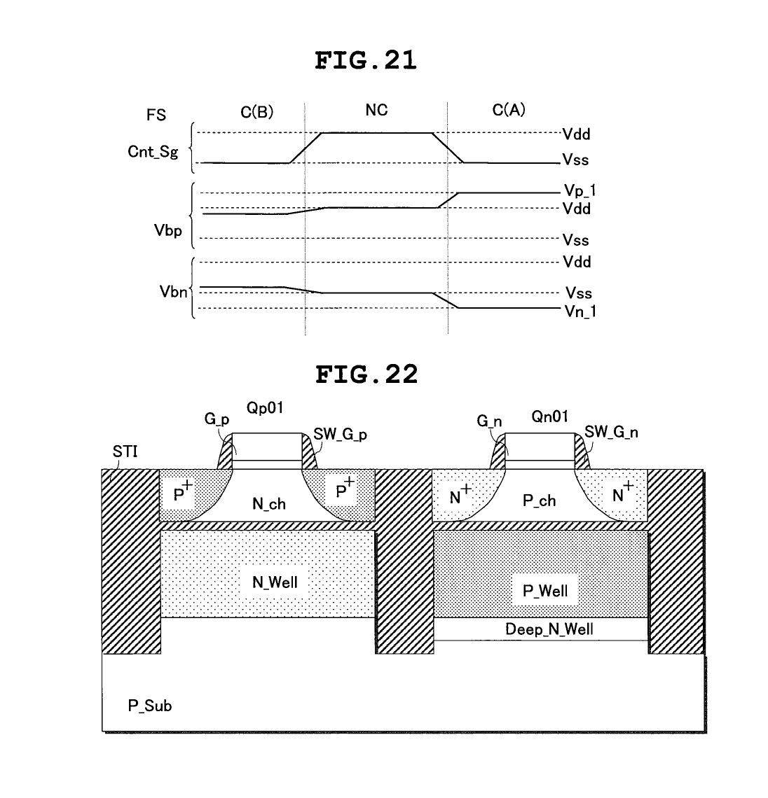

In FIG. 19, as is the case with FIG. 13, not only the fuse of the chip group A in which the threshold voltage Vth of the MOS LSI decreases to the lower threshold limit L_Lim or lower is cut as illustrated in FIG. 20A, but also the fuse of the chip group B in which the threshold voltage Vth of the MOS LSI exceeds the higher threshold limit H_Lim is cut as illustrated in FIG. 20B. However, the chip group B in which the threshold voltage Vth of the MOS LSI exceeds the higher threshold limit H_Lim is controlled as stated below. First, the N well bias voltage Vp_1 applied to the N well of the PMOS Qp01 of the core CMOS logic circuit “Core” through the PMOS Qpc_2 from the voltage generating unit CP_P of the PMOS control unit Cnt_P is changed to a voltage slightly lower in level than the power supply voltage Vdd. In addition, the P well bias voltage Vn_1 applied to the P well of the NMOS Qn01 of the core CMOS logic circuit “Core” through the NMOS Qnc_2 from the voltage generating unit CP_N of the NMOS control unit Cnt_N is changed to a voltage slightly higher in level than the ground voltage Vss. The relationship of voltages of each portion in the semiconductor integrated circuit illustrated in FIG. 19 at this point is shown as a cut state C(B) on the left side of FIG. 21. FIG. 21 is a chart illustrating the relationship of voltages of each portion in the semiconductor integrated circuit illustrated in FIG. 19. As illustrated in the cut state C(B) on the left side of FIG. 21, the N well bias voltage Vp_1 of the PMOS Qp01 is set to be slightly lower in level than the power supply voltage Vdd for the source and the P well bias voltage Vn_1 of the NMOS Qn01 is set to be slightly higher in level than the ground voltage Vss for the source. As a result, the threshold voltage of the PMOS Qp01 and the NMOS Qn01 of the core CMOS logic circuit “Core” lowers from an extra high threshold voltage Vth. The delay time of the core CMOS logic circuit “Core” is changed from an excessively long delay time to an appropriate delay time. FIGS. 20A and 20B are graphs describing the distribution of the threshold voltage Vth of the semiconductor integrated circuit illustrating in FIG. 19. The group B of the reproduced chips whose the threshold voltage Vth is higher than the upper limit threshold value H_Lim is changed to a reproduced chip group B_bv by the aforementioned control. As a result, an average threshold voltage Vth of all the PMOSs and the NMOSs in the core CMOS logic circuit “Core” of the MOS LSI chip lowers to the upper limit threshold value H_Lim or lower, enabling reducing the delay time of the entire chip.

### [SOI Device]

FIG. 22 is a cross section illustrating the semiconductor integrated circuit according to further another embodiment of the present invention. The MOS LSI illustrated in FIG. 22 uses the SOI structure. Incidentally, the SOI stands for Silicon-On-Insulator.

As illustrated in FIG. 22, the SOI structure has for example a P-type silicon substrate P_Sub in its lower layer. The N well N_Well and the P well P_Well are formed over the surface of the silicon substrate P_Sub of the lower layer. Incidentally, an STI layer is formed as an insulator element isolating region between the N well N_Well and the P well P_Well. The STI stands for Shallow Trench Isolation.

A thin insulator is formed on the surface of the silicon substrate P_Sub over which the N well N_Well and the P well P_Well are formed.

A silicon layer is formed over the thin insulator. On the left side of the silicon layer are formed the P-type source region and the P-type drain region with a high impurity density in the PMOS Qp01 and the N-type channel region controlled to an extremely low dose. On the right side of the silicon layer are formed the N-type source region and the N-type drain region with a high impurity density in the NMOS Qn01 and the P-type channel region controlled to an extremely low dose.

Since oxide film as the thin insulator is buried in the silicon layer, the thin insulator is called Buried Oxide, BOX. The N-type channel region of the PMOS Qp01 controlled to an extremely low dose is fully depleted and the P-type channel region of the NMOS Qn01 controlled to an extremely low dose is also fully depleted. Accordingly, the PMOS Qp01 and the NMOS Qn01 are fully-depleted “FD” SOI transistor. The threshold voltage of the PMOS Qp01 and the NMOS Qn01 of fully-depleted “FD” SOI transistors can be controlled by the substrate bias voltage of the N-well N_Well and the P well P_Well immediately under the thin insulator called back gate. The BOX FD-SOI transistor can substantially reduce the junction capacitance between the drain and the well thereof, so that the transistor is best suited for a high-speed and low-power consumption MOS LSI.

Although the invention made by the present inventors is described in detail with reference to the embodiments, it is to be understood that the present invention is not limited to the embodiments, but can be changed in various forms without departing from the gist of the invention.

For example, the PMOS substrate bias voltage Vbp of the PMOS Qp1, Qp2 and Qp3 and the NMOS substrate bias voltage Vbn of the NMOS Qn1, Qn2 and Qn3 in the standby mode are turned into a reverse-bias voltage far higher those in the active mode, thereby enabling reducing a leak current in the standby mode.

The present invention can be widely applied when variously used semiconductor integrated circuits of a microprocessor and a base band signal processor LSI as well as the system LSI are produced in a high yield and an operating power consumption for signal processing and the fluctuation of a signal delay are reduced.

What is claimed is:

1. A semiconductor integrated circuit comprising:
a CMOS circuit processing an input signal; and
an additional capacitance circuit produced in the same production process as the CMOS circuit,
wherein the CMOS circuit and the additional capacitance circuit include PMOSs and an additional PMOS with an N well and NMOSs and an additional NMOS with a P well,
wherein the sources of the PMOSs in the CMOS circuit and the additional PMOS in the additional capacitance circuit are electrically coupled to a first operating voltage wiring and the sources of the NMOSs in the CMOS circuit and the additional NMOS in the additional capacitance circuit are electrically coupled to a second operating voltage wiring,
wherein the N well can be supplied with a PMOS substrate bias voltage and the P well can be supplied with an NMOS substrate bias voltage, and
wherein the gate electrode of the additional PMOS in the additional capacitance circuit is electrically coupled to the N well and the gate electrode of the additional NMOS in the additional capacitance circuit is electrically coupled to the P well.

2. The semiconductor integrated circuit according to claim 1,
wherein a source-gate overlap capacitance between the source and the gate electrode of the additional PMOS of the additional capacitance circuit and a source-well junction capacitance between the source and the N well of the additional PMOS of the additional capacitance circuit are coupled at least in parallel between the first operating voltage wiring and the N well, and
wherein a source-gate overlap capacitance between the source and the gate electrode of the additional NMOS of the additional capacitance circuit and a source-well junction capacitance between the source and the P well of the additional NMOS of the additional capacitance circuit are coupled at least in parallel between the second operating voltage wiring and the P well.

3. The semiconductor integrated circuit according to claim 2,
wherein the source of the additional PMOS of the additional capacitance circuit is electrically coupled to the drain thereof and the source of the additional NMOS of the additional capacitance circuit is electrically coupled to the drain thereof,
wherein a drain-gate overlap capacitance between the drain and the gate electrode of the additional PMOS of the additional capacitance circuit and a drain-well junction capacitance between the drain and the N well of the additional PMOS of the additional capacitance circuit are further coupled in parallel between the first operating voltage wiring and the N well, and
wherein a drain-gate overlap capacitance between the drain and the gate electrode of the additional NMOS of the additional capacitance circuit and a drain-well junction capacitance between the drain and the P well of the additional NMOS of the additional capacitance circuit are further coupled in parallel between the second operating voltage wiring and the P well.

4. The semiconductor integrated circuit according to claim 1, further comprising:
a first voltage generating unit generating the PMOS substrate bias voltage from a first operating voltage supplied to the first operating voltage wiring; and a second voltage generating unit generating an NMOS substrate bias voltage from a second operating voltage supplied to the second operating voltage wiring.

5. The semiconductor integrated circuit according to claim 4,
wherein the PMOS substrate bias voltage supplied to the N well is reversely biased with respect to the first operating voltage supplied to the source of the PMOS of the CMOS circuit and the NMOS substrate bias voltage supplied to the P well is reversely biased with respect to the second operating voltage supplied to the source of the NMOS of the CMOS circuit, and
wherein the supply of the PMOS substrate bias voltage set to be higher in level than the first operating voltage to the N well controls the PMOSs with the N well at a high threshold voltage and a low leak current and the supply of the NMOS substrate bias voltage set to be lower in level than the second operating voltage to the P well controls the NMOSs with the P well at a high threshold voltage and a low leak current.

6. The semiconductor integrated circuit according to claim 5 further comprising a control memory storing control information for determining whether the PMOS substrate bias voltage set to be higher in level than the first operating voltage is supplied to the N well and whether the NMOS substrate bias voltage set to be lower in level than the second operating voltage is supplied to the P well.

7. The semiconductor integrated circuit according to claim 4,
wherein the PMOS substrate bias voltage supplied to the N well is forwardly biased with respect to the first operating voltage supplied to the source of the PMOS of the CMOS circuit and the NMOS substrate bias voltage supplied to the P well is forwardly biased with respect to the second operating voltage supplied to the source of the NMOS of the CMOS circuit, and
wherein the supply of the PMOS substrate bias voltage set to be lower in level than the first operating voltage to the N well controls the PMOSs with the N well at a low threshold voltage and a high leak current and the supply of the NMOS substrate bias voltage set to be higher in level than the second operating voltage to the P well controls the NMOSs with the P well at a low threshold voltage and a high leak current.

8. The semiconductor integrated circuit according to claim 7, further comprising a control memory storing control information for determining whether the PMOS substrate bias voltage set to be lower in level than the first operating voltage is supplied to the N well and whether the NMOS substrate bias voltage set to be higher in level than the second operating voltage is supplied to the P well.

9. The semiconductor integrated circuit according to claim 1,
wherein the CMOS circuit includes P-type high impurity density regions formed in the N well and N-type high impurity density regions formed in the P well, and
wherein a first diode including the P-type high impurity density region and the N well (N_Well) is coupled between the source and the N well of the PMOS of the CMOS circuit and a second diode including the N-type high impurity density region and the P well is coupled between the source and the P well of the NMOS of the CMOS circuit.

10. The semiconductor integrated circuit according to claim 1,
wherein the PMOSs of the CMOS circuit are those with an SOI structure,
wherein the NMOSs of the CMOS circuit are those with the SOI structure,
wherein the source and the drain of the PMOSs and of the NMOSs are formed in silicon over an insulating film with the SOI structure, and
wherein the N well of the PMOSs and the P well of the NMOSs are formed in a silicon substrate under the insulating film with the SOI structure.

11. A semiconductor integrated circuit comprising:
MOS circuits processing an input signal and an additional capacitance circuit produced in the same production process as the MOS circuits,
wherein the MOS circuit and the additional capacitance circuit include MOSs formed in a substrate and an additional MOS,
wherein the source of the MOSs of the MOS circuit and the additional MOS of the additional capacitance circuit are electrically coupled to a first operating voltage wiring,
wherein the substrate can be supplied with a MOS substrate bias voltage, and
wherein the gate electrode of the additional MOS of the additional capacitance circuit is electrically coupled to the substrate.

12. The semiconductor integrated circuit according to claim 11,
wherein a source-gate overlap capacitance between the source and the gate electrode of the additional MOS of the additional capacitance circuit and a source-substrate junction capacitance between the source and the substrate of the additional MOS of the additional capacitance circuit are coupled at least in parallel between the first operating voltage wiring and the substrate.

13. The semiconductor integrated circuit according to claim 12,
wherein the source of the additional MOS of the additional capacitance circuit is electrically coupled to the drain thereof, and
wherein a drain-gate overlap capacitance between the drain and the gate electrode of the additional MOS of the additional capacitance circuit and a drain-substrate junction capacitance between the drain and the substrate of the additional MOS of the additional capacitance circuit are further coupled in parallel between the first operating voltage wiring and the substrate.

14. The semiconductor integrated circuit according to claim 11, further comprising a voltage generating unit for generating the MOS substrate bias voltage from a first operating voltage supplied to the first operating voltage wiring.

15. The semiconductor integrated circuit according to claim 11,
wherein the MOS substrate bias voltage supplied to the substrate is reversely biased with respect to the first operating voltage supplied to the source of the MOS of the MOS circuit, and
wherein the supply of the MOS substrate bias voltage set to be lower in level than the first operating voltage to the substrate controls the MOSs formed in the substrate at a high threshold voltage and a low leak current.

16. The semiconductor integrated circuit according to claim 15, further comprising a control memory storing control information for determining whether the MOS substrate bias voltage set to be lower in level than the first operating voltage is supplied to the substrate.

17. The semiconductor integrated circuit according to claim 11,
wherein the MOS substrate bias voltage supplied to the substrate is forwardly biased with respect to the first operating voltage supplied to the source of the MOS of the MOS circuit, and
wherein the supply of the MOS substrate bias voltage set to be higher in level than the first operating voltage to the substrate controls the MOSs formed in the substrate at a low threshold voltage and a high leak current.

18. The semiconductor integrated circuit according to claim 17, further comprising a control memory storing control information for determining whether the MOS substrate bias voltage set to be higher in level than the first operating voltage is supplied to the substrate.

19. The semiconductor integrated circuit according to claim 11,
wherein the MOS circuit includes a high impurity density region formed in the substrate and a diode including the high impurity density region and the substrate is coupled between the source and the substrate of the MOS of the CMOS circuit.

20. The semiconductor integrated circuit according to claim 11,
wherein the MOSs of the MOS circuit are those with an SOI structure,
wherein the source and the drain of the MOSs are formed in silicon over an insulating film with the SOI structure, and
wherein the well of the MOSs is formed in a silicon substrate under the insulating film with the SOI structure.
